(19) United States
(12) Patent Application Publication
(10) Pub. No.: US 2025/0334453 A1
(43) Pub. Date: Oct. 30, 2025

(54) THERMAL DETECTION ELEMENT, METHOD OF MANUFACTURING THERMAL DETECTION ELEMENT, AND IMAGE SENSOR

(71) Applicant: SONY GROUP CORPORATION, TOKYO (JP)

(72) Inventors: TAISHI ANO, TOKYO (JP); KOJI KADONO, TOKYO (JP); SHINJI IMAIZUMI, TOKYO (JP)

(21) Appl. No.: 18/870,804

(22) PCT Filed: Jun. 8, 2022
(86) PCT No.: PCT/JP2022/023108

§ 371 Date: Dec. 2, 2024

(51) Int. Cl. G01J 5/12; G01J 5/00; H10N 10/01; H10N 10/17

(52) U.S. Cl. CPC G01J 5/12; H10N 10/01; H10N 10/17; G01J 2005/0077; G01J 2005/123

(57) ABSTRACT

A thermal detection element according to an embodiment of the present technology includes a substrate and a plurality of thermal detectors. Each of the plurality of thermal detectors is disposed on the substrate. Each of the plurality of thermal detectors includes a first electrode, a second electrode disposed on the substrate, a thermoelectric converter disposed between the first electrode and the second electrode, and an absorber that is disposed on the first electrode, and absorbs infrared rays and generates heat. The absorber included in each of the plurality of thermal detectors is configured to be separated from the absorber of another one of the thermal detectors.

### TECHNICAL FIELD

The present technology relates to a thermal detection element applicable to sensing using infrared rays, and the like, a method of manufacturing a thermal detection element, and an image sensor.

### BACKGROUND ART

Patent Literature 1 discloses an infrared detection element in which a plurality of thermocouples is formed on a substrate. In such an infrared detection element, a silicon needle with a small core diameter is embedded at the center of each thermocouple, which makes it possible to increase the integration density of the thermocouples. This makes it possible to detect infrared rays with high accuracy.

### Citation List

### Patent Literature

Patent Literature 1: Japanese Patent Application Laid- open No. 2011-117883

### DISCLOSURE OF INVENTION

### Technical Problem

As described above, there is a need for the technology that enables accurate detection of infrared rays.

In view of the circumstances as described above, it is an object of the present technology to provide a thermal detection element, a method of manufacturing a thermal detection element, and an image sensor that enable accurate detection of infrared rays.

### Solution to Problem

In order to achieve the above-mentioned object, a thermal detection element according to an embodiment of the present technology includes a substrate and a plurality of thermal detectors.

Each of the plurality of thermal detectors is disposed on the substrate.

Each of the plurality of thermal detectors includes a first electrode, a second electrode disposed on the substrate, a thermoelectric converter disposed between the first electrode and the second electrode, and an absorber that is disposed on the first electrode, and absorbs infrared rays and generates heat.

The absorber included in each of the plurality of thermal detectors is configured to be separated from the absorber of another one of the thermal detectors.

In such a thermal detection element, each of the plurality of thermal detectors includes an absorber that absorbs infrared rays and generates heat. The absorber included in each of the plurality of thermal detectors is configured to be separated from the absorber of another one of the thermal detectors. This makes it possible to detect infrared rays with high accuracy.

The absorber may have a shape of a rotating body. In this case, the absorber may have a bottom surface that is in contact with the first electrode, and a vertex located on the central axis of the rotating body.

The absorber may have a shape of a column. In this case, the absorber may have a bottom surface that is in contact with the first electrode.

The absorber may include a plurality of separate absorbers separated from each other.

Each of the plurality of separate absorbers may have a thread-like shape, a needle-like shape, or an arborescens shape.

The absorber may be formed of a material having an electrical conductivity of 10³ (S/m) or more and 10⁸ (S/m) or less.

The absorber may be formed of at least one selected from the group of elements consisting of aluminum, titanium, vanadium, copper, zinc, silver, tungsten, gold, lithium, beryllium, sodium, magnesium, potassium, calcium, strontium, barium, chromium, manganese, iron, cobalt, gallium, rubidium, molybdenum, indium, tin, hafnium, tantalum, carbon, silicon, germanium, arsenic, selenium, antimony, tellurium, and bismuth.

The absorber may be formed of at least one of graphene, carbon nanotube, black phosphorus, or a chalcogenide containing at least one selected from the group of elements.

The absorber may be formed of at least one of an oxide containing at least one selected from the group of elements, a nitride containing at least one selected from the group of elements, an oxynitride containing at least one selected from the group of elements, or a halide containing at least one selected from the group of elements.

The absorber may be formed of a conductive polymer.

The absorber may be formed of polypyrrole.

The absorber may be formed with the first electrode as a catalyst.

The thermoelectric converter may include a p-type thermoelectric conversion material and an n-type thermoelectric conversion material.

The thermal detection element may be a thermoelectric conversion element that generates an electromotive force by the heat generated by the absorber.

A method of manufacturing a thermal detection element according to an embodiment of the present technology includes:
a thermal detection member forming process of forming a plurality of thermal detection members on a substrate, each of the plurality of thermal detection members including a first electrode, a second electrode disposed on the substrate, and a thermoelectric converter disposed between the first electrode and the second electrode; and
an absorber forming process of forming, on the first electrode included in each of the plurality of thermal detection members, an absorber that absorbs infrared rays and generates heat.

The absorber forming process includes forming the absorber such that the absorbers respectively formed for the plurality of thermal detection members are configured to be separated from each other.

An image sensor according to an embodiment of the present technology includes the substrate and the plurality of thermal detection elements.

The plurality of thermal detection elements is disposed on the substrate.

### BRIEF DESCRIPTION OF DRAWINGS

FIG. 1 is a top view showing an example of the appearance of a thermal detection element according to an embodiment of the present technology.

FIG. 2 is a cross-sectional view taken along the line A-A of FIG. 1, where five or more thermal detectors are arranged in the X direction.

FIG. 3 is a cross-sectional view showing examples of an infrared absorber.

FIG. 4 is a flowchart showing an example of a method of manufacturing the thermal detection element.

FIG. 5 is a flowchart showing an example of the method of manufacturing the thermal detection element.

FIG. 6 is a cross-sectional view showing an example of the process of forming a thermal detection element.

FIG. 7 is a cross-sectional view showing an example of the process of forming the thermal detection element.

FIG. 8 is a cross-sectional view showing an example of the process of forming the thermal detection element.

FIG. 9 is a cross-sectional view showing an example of the process of forming the thermal detection element.

FIG. 10 is a cross-sectional view showing an example of the process of forming the thermal detection element.

FIG. 11 is a cross-sectional view showing a thermal detection element in a comparative example.

FIG. 12 is a cross-sectional view showing the thermal detection element in the comparative example.

FIG. 13 is a schematic view showing a thermal detection element according to the present technology.

FIG. 14 is a schematic view showing a thermal detection element according to the present technology.

FIG. 15 shows graphs showing an absorbance and a reflectance in a single film and a pillar A.

FIG. 16 is a schematic view showing an electric field distribution in the single film.

FIG. 17 is a schematic view showing an electric field distribution in the pillar A.

FIG. 18 is a schematic view showing an electric field distribution in a pillar B.

FIG. 19 shows graphs showing the relationship between a wavelength, an incidence angle perpendicular to the plane, a reflectance, and a transmittance in the pillar A and the pillar B.

FIG. 20 is a graph showing the absorbance in the single film and the pillar A.

FIG. 21 shows a graph and a table showing the absorbance and the like in the single film, the pillar A, and the pillar B.

FIG. 22 shows a graph and a table showing the absorbance and the like in the single film, the pillar A, and the pillar B.

FIG. 23 shows a graph and a table showing the absorbance and the like in the single film.

FIG. 24 is a table showing a thermal time constant and the like in the single film, a pillar A′, and a pillar B′.

FIG. 25 is a cross-sectional view showing an example of the process of forming a thermal detection element in a comparative example.

FIG. 26 is a cross-sectional view showing an example of the process of forming a thermal detection element according to the present technology.

### MODE(S) FOR CARRYING OUT THE INVENTION

Hereinafter, embodiments of the present technology will be described with reference to the drawings.

### Thermal Detection Element

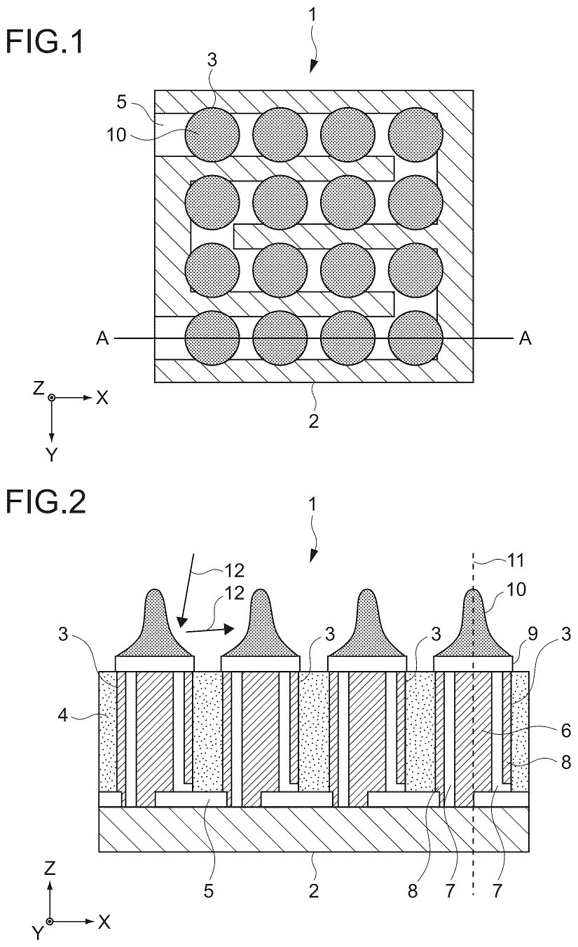

FIG. 1 is a top view showing an example of the appearance of a thermal detection element 1 according to an embodiment of the present technology.

FIG. 2 is a cross-sectional view taken along the line A-A of FIG. 1.

Hereinafter, description will be given with the X direction shown in each figure as the right and left direction, the Y direction as the depth direction, and the Z direction as the up and down direction, for convenience of explanation. Additionally, the positive side in the X direction (the side facing the arrow) is the right side, and the opposite negative side is the left side; the positive side in the Y direction is the front side, and the opposite negative side is the back side; the positive side in the Z direction is the upper side, and the opposite negative side is the lower side.

The thermal detection element 1 includes a substrate 2, a plurality of thermal detectors 3, and an insulating filler material 4.

The substrate 2 holds the plurality of thermal detectors 3 and the insulating filler material 4. In this embodiment, the substrate 2 functions as a heat sink. Additionally, various circuits and the like may be disposed on the substrate 2.

Each of the plurality of thermal detectors 3 is disposed on the substrate 2. As shown in FIG. 1, in this embodiment, the thermal detection element 1 includes 16 thermal detectors 3. The 16 thermal detectors 3 are disposed in a grid pattern, four in the right and left direction by four in the depth direction. In other words, as shown in FIG. 2, when the cross section of the thermal detection element 1 is viewed from the front side, four thermal detectors 3 are visible, which are disposed in the right and left direction. The number of thermal detectors 3 disposed is not limited and may be any number. The arrangement is also not limited to a grid pattern, and any arrangement may be adopted.

Each of the plurality of thermal detectors 3 includes a cold-point electrode 5, a p-type thermoelectric conversion material 6, an insulating material 7, an n-type thermoelectric conversion material 8, a warm-point electrode 9, and an infrared absorber 10.

The cold-point electrode 5 is disposed on the substrate 2. As shown in FIG. 2, two adjacent thermal detectors 3 are connected by the cold-point electrode 5. For example, the lower right portion of the leftmost thermal detector 3 and the lower left portion of the second leftmost thermal detector 3 are connected by the cold-point electrode 5.

Additionally, a rightmost thermal detector 3 in FIG. 2 is connected to a thermal detector 3 disposed behind it. In other words, as shown in FIG. 1, a rightmost thermal detector 3 on the front side and a rightmost thermal detector 3 that is second from the front side are connected by a cold-point electrode 5 extending in the depth direction. Note that FIG. 2 shows that a cold-point electrode 5 is disposed further toward the right with respect to the rightmost thermal detector 3 in FIG. 2. Thus, five or more thermal detectors 3 may be disposed in the right and left direction.

Similarly, a leftmost thermal detector 3 that is second from the front side is connected to a thermal detector 3 behind it. In such a way, the cold-point electrodes 5 are arranged such that the entire cold-point electrode 5 appears to be zigzag when viewed from the upper side as shown in FIG. 1.

For example, copper, aluminum, nickel, iron, and the like are used as materials for the cold-point electrode 5. Of course, the specific materials, shapes, and the like of the cold-point electrode 5 are not limited.

The p-type thermoelectric conversion material 6 is a material for converting heat into electric power. For example, the p-type thermoelectric conversion material 6 is formed of a p-type semiconductor. The p-type thermoelectric conversion material 6 has a substantially cylindrical shape and is disposed on the substrate 2 such that a portion of the bottom surface (generally on the left side relative to the center) comes into contact with the top surface of the substrate 2. Additionally, a portion of the bottom surface of the p-type thermoelectric conversion material 6 (generally on the right side relative to the center) comes into contact with the top surface of the cold-point electrode 5. On the bottom surface, a step may be provided between the portion in contact with the substrate 2 and the portion in contact with the cold-point electrode 5. The specific material, shape, and arrangement of the p-type thermoelectric conversion material 6 are not limited.

The insulating material 7 is a material for electrically insulating the p-type thermoelectric conversion material 6 and the n-type thermoelectric conversion material 8. For example, the insulating material 7 is formed of an insulator. The insulating material 7 has a substantially cylindrical shape and is disposed such that the p-type thermoelectric conversion material 6 is fitted into the hollow of the cylinder. The bottom surface of the insulating material 7 has an annular shape and is disposed on the substrate 2 such that a portion of the bottom surface (generally on the left side relative to the center) is in contact with the top surface of the substrate 2. Additionally, a portion of the bottom surface of the insulating material 7 (generally on the right side relative to the center) is in contact with the top surface of the cold-point electrode 5. The specific material, shape, and arrangement of the insulating material 7 is not limited.

The n-type thermoelectric conversion material 8 is a material for converting heat into electric power. For example, the n-type thermoelectric conversion material 8 is formed of an n-type semiconductor. The n-type thermoelectric conversion material 8 has a substantially cylindrical shape and is disposed such that the insulating material 7 is fitted into the hollow of the cylinder. The bottom surface of the n-type thermoelectric conversion material 8 has an annular shape and is disposed on the substrate 2 such that a portion of the bottom surface (generally on the left side relative to the center) is in contact with the top surface of the substrate 2 and with the top surface of the cold-point electrode 5. Additionally, a portion of the bottom surface of the n-type thermoelectric conversion material 8 (generally on the right side relative to the center) is in contact with the insulating material 7. The specific material, shape, and arrangement of the n-type thermoelectric conversion material 8 are not limited.

The left-hand end of each cold-point electrode 5 is connected to the p-type thermoelectric conversion material 6 and is not connected to the n-type thermoelectric conversion material 8. Additionally, the right-hand end of each cold-point electrode 5 is connected to the n-type thermoelectric conversion material 8 and is not connected to the p-type thermoelectric conversion material 6. Additionally, the p-type thermoelectric conversion material 6 and the n-type thermoelectric conversion material 8 are disposed between the warm-point electrode 9 and the cold-point electrode 5.

Note that the p-type thermoelectric conversion material 6 and the n-type thermoelectric conversion material 8 may be disposed inversely. In other words, the p-type thermoelectric conversion material 6 may be disposed on the outer circumference side of the thermal detector 3, and the n-type thermoelectric conversion material 8 may be disposed inside thereof.

The warm-point electrode 9 has a disc shape and is disposed such that its bottom surface is in contact with the top surfaces of the p-type thermoelectric conversion material 6, the insulating material 7, and the n-type thermoelectric conversion material 8. The specific shape of the warm-point electrode 9 is not limited, and the warm-point electrode 9 may have other shapes such as a square shape. The specific material of the warm-point electrode 9 is also not limited.

The infrared absorber 10 absorbs infrared rays and generates heat. In this embodiment, the infrared absorber 10 has the shape of a rotating body and has a bottom surface and a vertex. The bottom surface of the infrared absorber 10 is circular, and the infrared absorber 10 is disposed on the warm-point electrode 9 such that the entire bottom surface of the infrared absorber 10 is in contact with the top surface of the warm-point electrode 9. Additionally, the infrared absorber 10 is disposed such that the central axis of the infrared absorber 10 coincides with the central axis of the p-type thermoelectric conversion material 6, the insulating material 7, and the n-type thermoelectric conversion material 8. FIG. 2 shows the central axis 11 of the p-type thermoelectric conversion material 6, the insulating material 7, the n-type thermoelectric conversion material 8, and the infrared absorber 10 by a dashed line. The vertex of the infrared absorber 10 is located on the central axis. In this embodiment, the infrared absorber 10 has the shape of a bell or the shape of a normal distribution by the Gaussian function, as shown in FIG. 2. Of course, the specific shape of the infrared absorber 10 is not limited. Note that the constituent materials of the infrared absorber 10 will be described later in detail.

The insulating filler material 4 is a material for electrically and thermally insulating the thermal detectors 3. For example, the insulating filler material 4 is formed of an insulator. The insulating filler material 4 is filled to fill the cavities between the thermal detectors 3. The specific material of the insulating filler material 4 is not limited. Additionally, it is also possible to adopt a configuration without the insulating filler material 4. Note that in FIG. 1 the illustration of the insulating filler material 4 is omitted.

The warm-point electrode 9 corresponds to an embodiment of a first electrode according to the present technology. The cold-point electrode 5 corresponds to an embodiment of a second electrode according to the present technology. The p-type thermoelectric conversion material 6 and the n-type thermoelectric conversion material 8 correspond to an embodiment of a thermoelectric converter according to the present technology. The infrared absorber 10 corresponds to an embodiment of an absorber according to the present technology.

The infrared absorber 10 included in each of the plurality of thermal detectors 3 is configured to be separated from the infrared absorbers 10 included in the other thermal detectors 3. In other words, an infrared absorber 10 of one thermal detector 3 is not in contact with infrared absorbers 10 of any other thermal detectors 3. Thus, in this embodiment, each of the infrared absorbers 10 is independently disposed for each of the thermal detectors 3.

### Detection of Infrared Light

Infrared light is detected by the thermal detection element 1. Hereinafter, specific details regarding the detection of infrared light will be described.

FIG. 2 schematically shows infrared light 12 incident on the infrared absorbers 10 by using arrows. The infrared light 12 is infrared light that exists in the space outside the thermal detection element 1. For example, infrared light derived from heat emitted from animals including humans, or plants, can enter the infrared absorbers 10 as the infrared light 12.

In the example shown in FIG. 2, the infrared light 12 first enters the leftmost infrared absorber 10. The infrared light 12 is then reflected by the leftmost infrared absorber 10 and enters the second infrared absorber 10 from the left side.

When the infrared light 12 enters the infrared absorber 10, the infrared light 12 is absorbed by the infrared absorber 10, and heat is generated in the infrared absorber 10. The generated heat is also transferred to the upper part of the p-type thermoelectric conversion material 6 via the warm-point electrode 9, and the upper part of the p-type thermoelectric conversion material 6 becomes heated.

Since the substrate 2 functions as a heat sink, when the heat on the upper part of the p-type thermoelectric conversion material 6 propagates to the lower part, the heat is exhausted through the substrate 2. Therefore, the lower part of the p-type thermoelectric conversion material 6 has a lower temperature than the upper part.

Therefore, a temperature difference is generated at the upper part and the lower part of the p-type thermoelectric conversion material 6. At that time, an electromotive force is generated inside the p-type thermoelectric conversion material 6 due to an thermoelectric effect (Seebeck effect). Similarly, since a temperature difference is also generated at the upper part and the lower part of the n-type thermoelectric conversion material 8, an electromotive force is also generated inside the n-type thermoelectric conversion material 8.

As shown in FIG. 2, the cold-point electrode 5 is connected to the n-type thermoelectric conversion material 8 on its right side. The n-type thermoelectric conversion material 8 is connected to the warm-point electrode 9 on its upper side. The warm-point electrode 9 is connected to the p-type thermoelectric conversion material 6 on its lower side. The p-type thermoelectric conversion material 6 is connected to the cold-point electrode 5 on its lower side. The cold-point electrode 5 is connected to the n-type thermoelectric conversion material 8 of the thermal detector 3 adjacent thereto. Note that the p-type thermoelectric conversion material 6 and the n-type thermoelectric conversion material 8 are insulated by the insulating material 7, and thus they are not directly connected to each other.

In such a way, the members are electrically connected to form a single open circuit having a zigzag shape as a whole, as shown in FIG. 1. Since an electromotive force is generated in each of the p-type thermoelectric conversion material 6 and the n-type thermoelectric conversion material 8 that constitute the open circuit, a potential difference is generated at both ends of the open circuit (a cold-point electrode 5 on the left and back side, and a cold-point electrode 5 on the left and front side).

Therefore, when the both ends of the open circuit are electrically connected to each other through an object, a current flows to the connected object. The value of this current is a value that depends on the intensity of the infrared light 12 incident on the infrared absorber 10. Therefore, measuring the value of the current makes it possible to detect the infrared light 12.

### Variations of Infrared Absorber

The specific shape of the infrared absorber 10 is not limited to a bell shape. Hereinafter, variations in the shape of the infrared absorber 10 will be described.

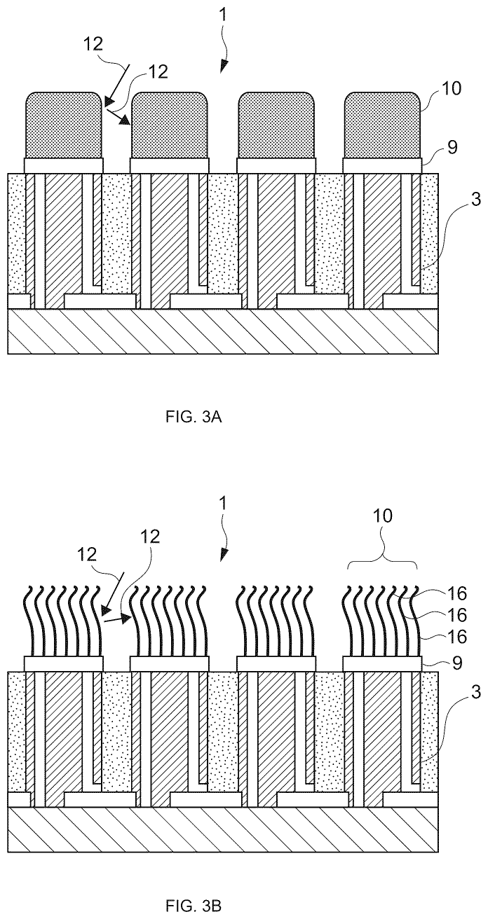

FIG. 3 is a cross-sectional view showing examples of the infrared absorber 10.

In the example shown in A of FIG. 3, the infrared absorber 10 has the shape of a column. Further, the bottom surface of the infrared absorber 10 is in contact with the warm-point electrode 9. Also in this example, the infrared light 12 can be reflected by one infrared absorber 10 and absorbed by an adjacent infrared absorber 10. Note that the shape of the column of the infrared absorber 10 shown in A of FIG. 3 may be generally described as a non-tapered shape, a pillar shape, or the like. Similarly, the bell shape of the infrared absorber 10 shown in FIG. 2 may be described as a tapered shape, a pillar shape, or the like.

In the example shown in B of FIG. 3, the infrared absorber 10 includes a plurality of separate infrared absorbers 16. In this example, each of the separate infrared absorbers 16 is configured such that seven separate infrared absorbers 16 are visible when a cross-section of the thermal detection element 1 is viewed. Of course, the number of separate infrared absorbers 16 constituting the infrared absorber 10 is not limited. For example, any configuration can be adopted, in which two separate infrared absorbers 16 are disposed separately on the warm-point electrode 9, or a very large number of separate infrared absorbers 16 are disposed. Additionally, the separate infrared absorbers may also be partially connected.

Each of the plurality of separate infrared absorbers 16 has a thread-like, needle-like, or arborescens shape. Specifically, the separate infrared absorber 16 has a shape that extends generally up and down with one end thereof being connected to the warm-point electrode 9 and is curved in the right and left direction and in the depth direction. Additionally, each of the plurality of separate infrared absorbers 16 may have a nanowire-like shape as a thread-like shape. The separate infrared absorber 16 may also have a whisker-like shape as a needle-like shape. The separate infrared absorber 16 may also have a dendrite-like shape as a branching arborescens shape. In this example as well, the infrared light 12 may be reflected by one separate infrared absorber 16 and absorbed by a separate infrared absorber 16 of an adjacent thermal detector 3. Additionally, the infrared light 12 may also be absorbed by a separate infrared absorber 16 of the same thermal detector 3.

Note that, regarding the separate infrared absorbers 16 shown in B of FIG. 3, in this example, all of the separate infrared absorbers 16 have the same shape, but may have different shapes. Additionally, the specific shape of the separate infrared absorber 16 is not limited. The separate infrared absorber 16 corresponds to an embodiment of a separate absorber according to the present technology.

Additionally, each of the thermal detectors 3 may include an infrared absorber 10 of a different shape for each of the thermal detector 3. For example, an infrared absorber 10 having the shape of a column may be disposed on the upper part of one warm-point electrode 9, while an infrared absorber 10 including a plurality of separate infrared absorbers 16 may be disposed on another warm-point electrode 9.

### Method of Manufacturing Thermal Detection Element

A specific method of manufacturing the thermal detection element 1 will be described.

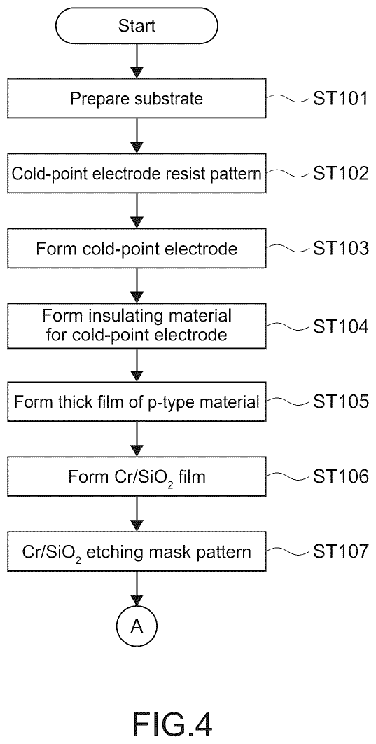

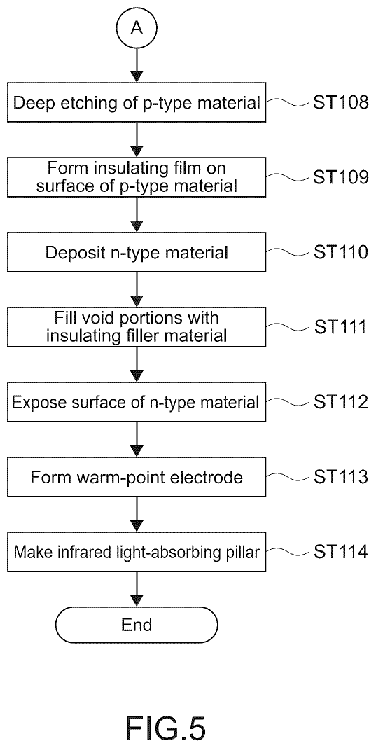

FIGS. 4 and 5 are flowcharts showing an example of a method of manufacturing the thermal detection element 1.

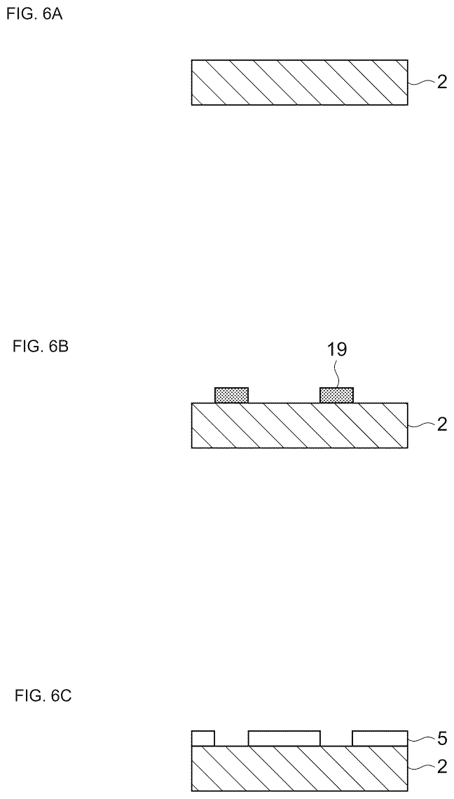

FIGS. 6 to 10 are cross-sectional views showing an example of the process of forming the thermal detection element 1.

A substrate 2 is prepared (Step 101). As shown in A of FIG. 6, a substrate 2 is disposed.

A cold-point electrode resist pattern 19 is disposed (Step 102). As shown in B of FIG. 6, a cold-point electrode resist pattern 19 is disposed on the top surface of the substrate 2 to form a cold-point electrode 5.

A cold-point electrode 5 is formed (Step 103). Specifically, the material of the cold-point electrode 5 is filled in the spaces between the cold-point electrode resist patterns 19 disposed as shown in B of FIG. 6. Thus, the cold-point electrode 5 is formed in the space portion as shown in C of FIG. 6.

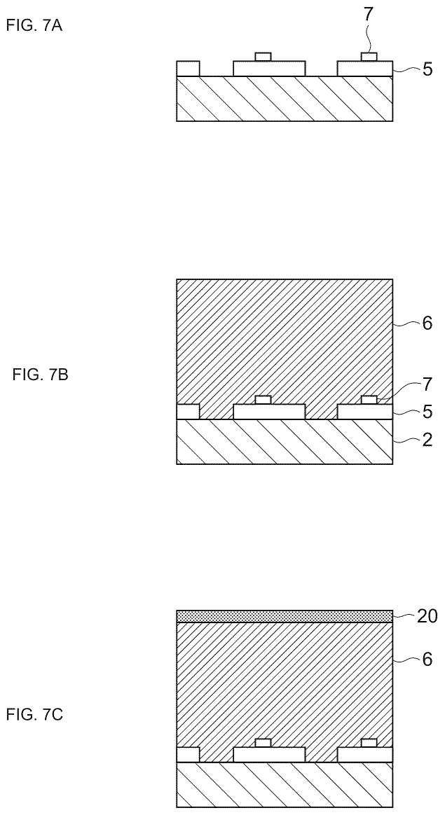

An insulating material 7 is formed for the cold-point electrode 5 (Step 104). As shown in A of FIG. 7, an insulating material 7 is disposed on the upper part of each cold-point electrode 5. The insulating material 7 disposed in A of FIG. 7 becomes a part of the insulating material 7 (when completed) shown in FIG. 2.

A thick film of a p-type thermoelectric conversion material 6 is formed (Step 105). As shown in B of FIG. 7, a thick film of a p-type thermoelectric conversion material 6 is formed in the space on the upper side of the substrate 2, the cold-point electrode 5, and the insulating material 7.

A Cr/SiO₂ (chromium, silicon dioxide) film 20 is formed (Step 106). As shown in C of FIG. 7, a Cr/SiO₂ film 20 is formed on the upper part of the thick film of the p-type thermoelectric conversion material 6.

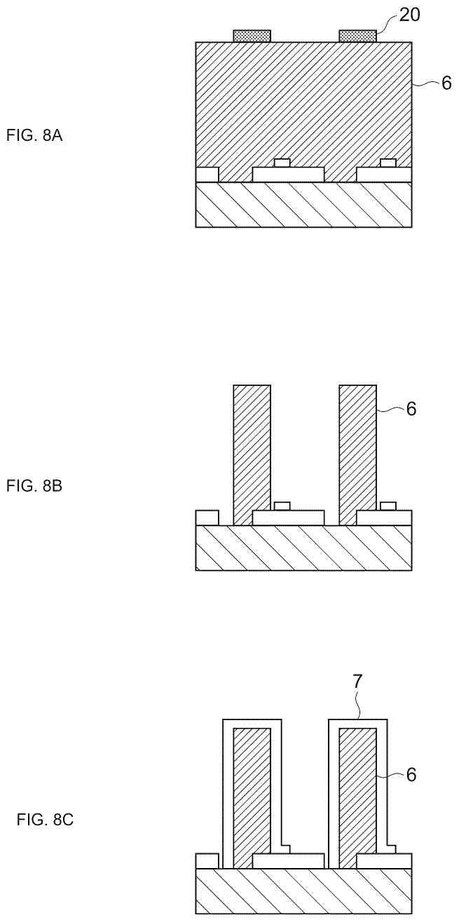

An etching mask pattern is formed (Step 107). As shown in A of FIG. 8, a mask pattern using the Cr/SiO₂ film 20 is formed so as to etch the thick film of the p-type thermoelectric conversion material 6.

The thick film of the p-type thermoelectric conversion material 6 is etched (Step 108). As shown in B of FIG. 8, the lower side of a portion of the thick film of the p-type thermoelectric conversion material 6, where the Cr/SiO₂ film 20 is disposed, remains unetched.

An insulating film is formed on the surface of the p-type thermoelectric conversion material 6 (Step 109). As shown in C of FIG. 8, an insulating material 7 is formed on the surface of the p-type thermoelectric conversion material 6. For example, an atomic layer deposition (ALD) technology is used to form an insulating film.

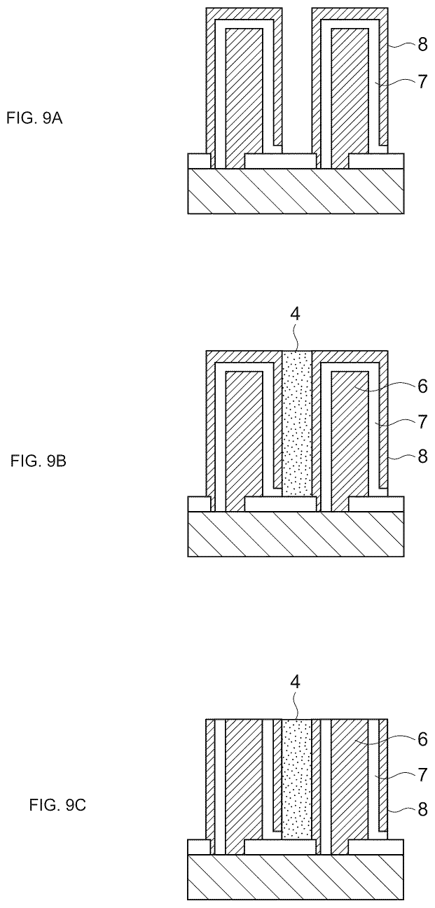

An n-type thermoelectric conversion material 8 is deposited (Step 110). As shown in A of FIG. 9, an n-type thermoelectric conversion material 8 is formed on the surface of the insulating material 7. For example, a material having high adhesion to the insulating material 7 is used as the n-type thermoelectric conversion material 8. Additionally, a technique such as the atomic layer deposition technology, chemical vapor deposition (CVD), or plating is used.

Void portions are filled with the insulating filler material 4 (Step 111). Specifically, as shown in B of FIG. 9, the spaces between the n-type thermoelectric conversion materials 8 are filled with the insulating filler material 4.

The surface of the n-type thermoelectric conversion material 8 is exposed (Step 112). Specifically, in the state shown in B of FIG. 9, the upper parts of the insulating filler material 4, the p-type thermoelectric conversion material 6, the insulating material 7, and the n-type thermoelectric conversion material 8 are shaved by soft etching and polishing. Thus, the p-type thermoelectric conversion material 6 and the insulating material 7, which are not exposed in B of FIG. 9, are now exposed on the upper side, as shown in C of FIG. 9.

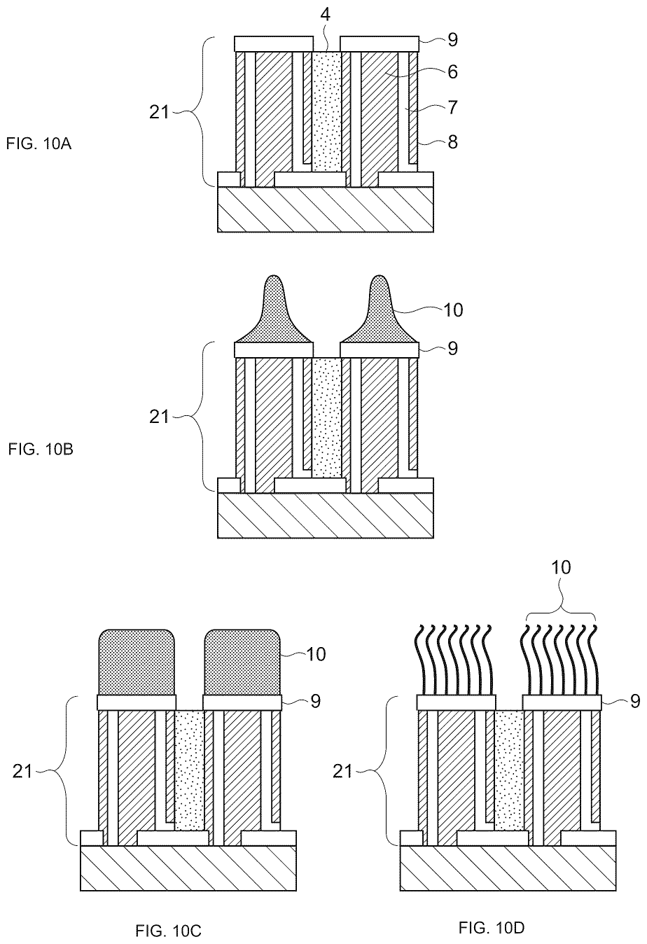

A warm-point electrode 9 is formed (Step 113). As shown in A of FIG. 10, a warm-point electrode 9 is formed so as to come into contact with the top surfaces of the insulating filler material 4, the p-type thermoelectric conversion material 6, the insulating material 7, and the n-type thermoelectric conversion material 8.

An infrared light-absorbing pillar is made (Step 114). As shown in B to D of FIG. 10, an infrared absorber 10 is formed on the top surface of the warm-point electrode 9.

### Manufacture of Infrared Absorber

The method of manufacturing the infrared absorber 10 on the top surface of the warm-point electrode 9 is not limited. An example of the method of manufacturing the infrared absorber 10 will be described below.

### Manufacture of Au/Al₂O₃ Pillar

In this technique, aluminum is first manufactured as a pattern electrode by a technique such as thermal deposition. Next, electrochemical oxidation treatment is performed at a temperature of 80° C. or below. Thus, an Al₂O₃ pillar having a height of 5 μm is formed on the warm-point electrode 9 via a hexagonal structure of an aluminum oxide (Al₂O₃). Next, Au sputtering (gold sputtering) is performed on the Al₂O₃ pillar. Thus, the infrared absorption capability by AuBlack is provided to the Al₂O₃ pillar.

This technique makes it possible to manufacture an infrared absorber 10 having the shape of a bell, for example. Since the electrochemical technique provides a high film formation rate, it is possible to manufacture a tall microstructure in a short time. In addition, since it is a simple process based on liquid-phase synthesis and sputtering, it is possible to reduce apparatus and processing costs.

Additionally, it is a low-temperature process at a temperature of 100° C. or lower and thus can be applied to materials that are sensitive to high temperature, thus avoiding process restrictions.

### Manufacture of CNTs Pillar by Catalytic CVD Technique

In this technique, a catalytic metal (such as iron) is first introduced on the pattern electrode. Further, methanol is introduced with argon gas as a carrier gas in an environment of 400° C. to 650° C. This allows carbon nano-tubes (CNTs) pillars with an infrared absorption capability to grow on the catalyst metal.

This technique makes it possible to manufacture, for example, separate infrared absorbers 16 having an arborescens shape. Since CVD provides a high film formation rate, it is possible to manufacture a tall microstructure in a relatively short time. In addition, performing only one process of CVD makes it possible to achieve a complex nanostructure or the separate infrared absorbers 16 having an arborescens shape. Additionally, since an etching process to cut the gap between the pillars is not included, material and processing costs can be reduced.

### Catalytic CVD Film-Formation of CNTs on Al Pillar Surface (1)

In this technique, an Al (aluminum) film is first formed by electroplating or the like, and then formed into a pillar by a NaCl (sodium chloride) aqueous solution or the like. A Fe/Co (iron and cobalt) catalyst metal is formed on the surface of the Al pillar. Further, acetylene is introduced with argon gas as a carrier gas in an environment of 400° C. to 600° C. Thus, CNTs pillars with the infrared absorption capability are selectively caused to grow only on the catalyst metal.

Use of this technique makes it possible to manufacture an Al microstructure in a low-cost process using the NaCl aqueous solution. In addition, since CVD provides a high film formation rate among deposition methods, it is possible to manufacture a tall microstructure in a relatively short time. Further, CNTs can be deposited at a low temperature of 400° C.

### Catalytic CVD Film-Formation of CNTs on Al Pillar Surface (2)

In this technique, a Zn/Ni (zinc, nickel) alloy is first deposited by a technique such as electroplating. Further, either a liquid-phase process in an alkali bath or a high-temperature evaporation process at a temperature of 200° C. to 400° C. is utilized to selectively remove only Zn.

The resulting porous Ni has a high infrared absorption capability due to its electrical conductivity and microstructure. This technique allows selective electroplating deposition to be performed directly on the thermoelectric pillar in a short time. Additionally, since it does not involve high temperature processes when alloy formation and selective metal removal are performed, it is also possible to avoid restrictions on applicable materials and device processes. In addition, since it is a liquid-phase process, material and processing costs can be reduced.

### Formation of Graphene Absorption Layer

In this technique, plasma etching using argon is first performed on the electrode layer on the topmost surface of the device to form surface nano-level irregularities. Next, a graphene catalyst layer (iron) is formed by sputtering. Further, a graphene precursor layer (amorphous carbon) is formed by sputtering. Furthermore, graphene is then formed by annealing at a temperature of 300° C. to 800° C.

Use of this technique makes it possible to manufacture an absorption layer with a high absorption rate (99%) in a very thin film (15 nm). In addition, since the plasma etching and the two times of sputtering deposition are performed by the same apparatus, a simple process is achieved. Further, selecting a catalyst layer of Ni or the like makes it possible to form graphene at a temperature around 350° C.

### Formation of Si Nanowire Structure

In this technique, a silicon (Si) layer is first prepared on the topmost surface of the device. Next, a protective layer of resist is formed on the back surface of the device. Next, a pattern is formed by photolithography on the surface of the Si layer. Next, a Si nanowire structure (Si-NWs) is formed by dry etching. Alternatively, the device may be immersed into an Ag nanoparticles (Ag-NPs) catalyst solution (AgNO₃ (silver nitrate (I)/HF (hydrogen fluoride)/H₂O (water)/H₂O₂ (hydrogen peroxide), 50° C.) to form Si-NWs by a wet etching process. Next, a film of resist is formed on the topmost surface of the device, and a pattern is formed by photolithography. Finally, unwanted Si layers are removed by dry etching.

This technique uses the steps in the existing semiconductor process, such as bonding. Since high-temperature processes do not exist, this technique can be used in the steps after device formation.

### Electrophoretic Film-Formation Based on Polymerization of Pyrrole with Entrapped Black Phosphorus

In this technique, pyrrole polymerization is performed electrochemically with black phosphorus nanosheets being dispersed in a pyrrole solution. At that time, a composite film of black phosphorus/polypyrrole is formed by entrapping the black phosphorus.

In this technique, a pyrrole dispersion of black phosphorus nanosheets can be prepared in advance to perform electrochemical film-formation in a short time. Additionally, since it does not involve high temperature processes, it is also possible to avoid restrictions on applicable materials and device processes. In addition, since it is a liquid-phase process, material and processing costs can be reduced. Additionally, black phosphorus is known as a material with a high infrared absorption capability.

### Pressing by Stamping Method

In this technique, other materials are pressed against the electrode directly on the thermoelectric element pillar using a stamping method to manufacture infrared absorbing materials such as black phosphorus and sulfides. For example, a Cu (copper) electrode is brought into contact with sulfur, which makes it possible to manufacture Cu₂S (copper sulfide (I)) that has a microstructure and is expected to have a high infrared absorption capability. In addition, for example, black phosphorus serving as a two-dimensional material, which is easily peeled off, is brought into contact with an electrode, which makes it possible to provide an infrared absorption capability through the adsorption of a thin black phosphorus film on the metal surface. Note that the black phosphorus can be replaced with other two-dimensional materials.

This technique allows for the conversion of a pillar-shaped electrode into an infrared absorber and the manufacture of an infrared absorber pillar in a simple process.

As described above, various techniques can be used in the process of forming the infrared absorber 10 for the warm-point electrode 9. Of course, the infrared absorber 10 may be formed by any method, not limited to those techniques.

Note that the infrared absorber 10 may be formed with the warm-point electrode 9 used as a catalyst. In other words, for example, instead of introducing a catalytic metal on the warm-point electrode 9, the warm-point electrode 9 itself may be formed of a catalytic metal such as iron. This omits the process of introducing a catalytic metal on the warm-point electrode 9 and further facilitates the manufacture of the infrared absorber 10.

The warm-point electrode 9, the cold-point electrode 5, the p-type thermoelectric conversion material 6, the insulating material 7, and the n-type thermoelectric conversion material 8 each correspond to an embodiment of a thermal detection member according to the present technology.

Additionally, the process of Steps 101 to 113 corresponds to an embodiment of a thermal detection member forming process according to the present technology. In other words, in the processing of Steps 101 to 113, a plurality of thermal detection members 21 including the warm-point electrode 9, the cold-point electrode 5, the p-type thermoelectric conversion material 6, and the n-type thermoelectric conversion material 8 is formed.

The process of Step 114 corresponds to an embodiment of an absorber forming process according to the present technology. In other words, an infrared absorber 10 is formed for the warm-point electrode 9 included in each of the plurality of thermal detection members 21.

Additionally, in the process of Step 114, the infrared absorbers 10 are formed such that the infrared absorbers 10 respectively formed for the plurality of thermal detection members 21 are configured to be separated from each other.

### Material of Infrared Absorber

The specific materials of the infrared absorber 10 are not limited. Hereinafter, materials that have particular practical potential as materials of the infrared absorber 10 will be described.

For example, the infrared absorber 10 is formed of a material having an electrical conductivity of 10³ (S/m) or more and 10⁸ (S/m) or less.

Specifically, for example, the infrared absorber 10 is formed of at least one selected from the group of elements consisting of aluminum, titanium, vanadium, copper, zinc, silver, tungsten, gold, lithium, beryllium, sodium, magnesium, potassium, calcium, strontium, barium, chromium, manganese, iron, cobalt, gallium, rubidium, molybdenum, indium, tin, hafnium, tantalum, carbon, silicon, germanium, arsenic, selenium, antimony, tellurium, and bismuth. Additionally, other near-metallic, near-semi-metallic, or near-semiconductor elements are also used.

In addition, for example, the infrared absorber 10 is formed of at least one of graphene, carbon nanotube, black phosphorus, or chalcogenide containing at least one selected from the group of elements described above. For example, the infrared absorber 10 is formed of a chalcogenide material such as Cu₂S, MoS₂ (molybdenum sulfide (IV)), SnSe (tin selenide (II)), or BiTe (bismuth telluride). Alternatively, a two-dimensional material such as stannene, selenene, tellurene, or bismuthene is used.

Additionally, for example, the infrared absorber 10 is formed of at least one of an oxide containing at least one selected from the group of elements, a nitride containing at least one selected from the group of elements, an oxynitride containing at least one selected from the group of elements, or a halide containing at least one selected from the group of elements.

Additionally, for example, the infrared absorber 10 is formed of a conductive polymer. Specifically, for example, for example, the infrared absorber 10 is formed of polypyrrole. Alternatively, a conductive polymer such as polyaniline or polythiophene may be used.

A composite material combining those materials may be used. Any other materials having an electrical conductivity of 10³ (S/m) or more and 10⁸ (S/m) or less may be used.

As described above, in the thermal detection element 1 according to this embodiment, each of the plurality of thermal detectors 3 includes an infrared absorber 10 that absorbs infrared rays and generates heat. The infrared absorber 10 included in each of the plurality of thermal detectors 3 is configured to be separated from the infrared absorber 10 of another one of the thermal detectors 3. This makes it possible to detect infrared rays with high accuracy.

To achieve high sensitivity and fast response of the infrared detection element, it is necessary to achieve efficient absorption of infrared light in the vicinity of the thermoelectric converter. On the other hand, to provide a sufficient amount of absorption, it is necessary to design a thick infrared light-absorbing layer that prevents light leakage. The thick infrared light-absorbing layer has large thermal capacity and thermal resistance, resulting in slow response speed.

Reducing the thickness of the infrared light-absorbing layer improves the response speed, but the amount of infrared light absorption is reduced, resulting in reduced sensitivity. As a solution to this problem, designing a fine concavo-convex structure is effective. However, the infrared detection element requires an umbrella-shaped absorbing layer that is partially hollow to take advantage of in-plane temperature differences. In addition, there have been structural and process limitations, such as the need to manufacture an insulating layer before constructing the absorbing layer in order to prevent a short circuit from occurring in the temperature-sensitive portions and wiring within the element.

In the thermal detection element 1 according to the present technology, the infrared absorber 10 included in each of the plurality of thermal detectors 3 is configured to be separated from each other. The infrared absorber 10 is configured in such a manner, so that a high absorbance can be achieved and efficient infrared light detection can be performed.

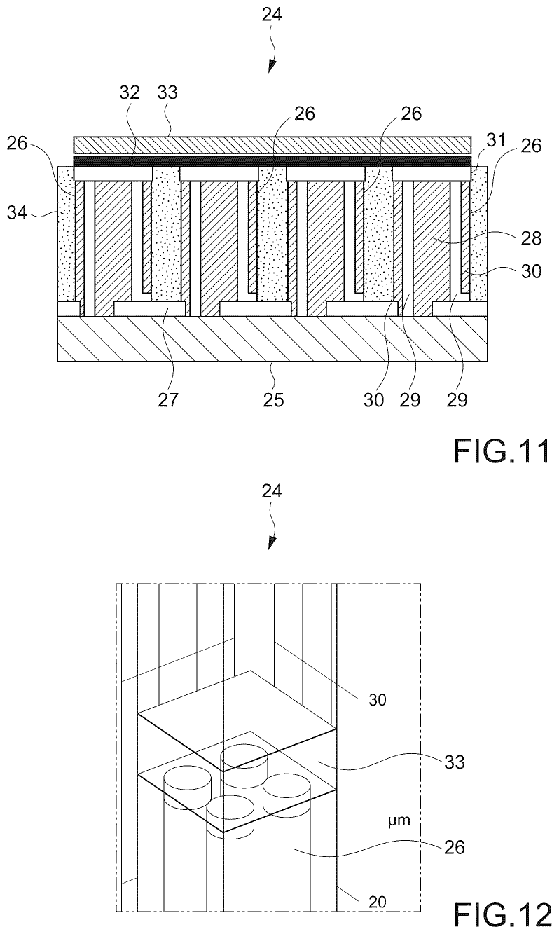

FIG. 11 is a cross-sectional view showing a thermal detection element 24 in a comparative example.

The thermal detection element 24 in the comparative example includes a substrate 25, a plurality of thermal detectors 26, and an insulating filler material 34, similarly to the thermal detection element 1 according to the present technology. Additionally, each of the plurality of thermal detectors 26 includes a cold-point electrode 27, a p-type thermoelectric conversion material 28, an insulating material 29, an n-type thermoelectric conversion material 30, and a warm-point electrode 31. In addition, the thermal detection element 24 includes an electrically insulating thermal conductor 32 and an infrared absorbing film 33.

The electrically insulating thermal conductor 32 is a thermal conductor for electrically insulating the warm-point electrodes 31 and the infrared absorbing film 33. The electrically insulating thermal conductor 32 has a film shape and is disposed across the warm-point electrodes 31 such that the bottom surface thereof is in contact with the top surfaces of the respective warm-point electrodes 31.

The infrared absorbing film 33 absorbs infrared rays and generates heat. The infrared absorbing film 33 is disposed on the upper portion of the electrically insulating thermal conductor 32 such that the bottom surface thereof is in contact with the top surface of the electrically insulating thermal conductor 32.

If the electrically insulating thermal conductor 32 is not disposed, the warm-point electrodes 31 are electrically connected to each other through the infrared absorbing film 33. To prevent this, the electrically insulating thermal conductor 32 is disposed. Note that the electrically insulating thermal conductor 32 does not thermally insulate each of the warm-point electrodes 31 and the infrared absorbing film 33. In other words, the heat generated in the infrared absorbing film 33 propagates through the electrically insulating thermal conductor 32 to the warm-point electrodes 31.

### Experiments

The inventors performed experiments to compare the absorbance and the like of the thermal detection element 1 according to the present technology and the thermal detection element 24 in the comparative example.

FIG. 12 is a schematic view showing the thermal detection element 24 in the comparative example.

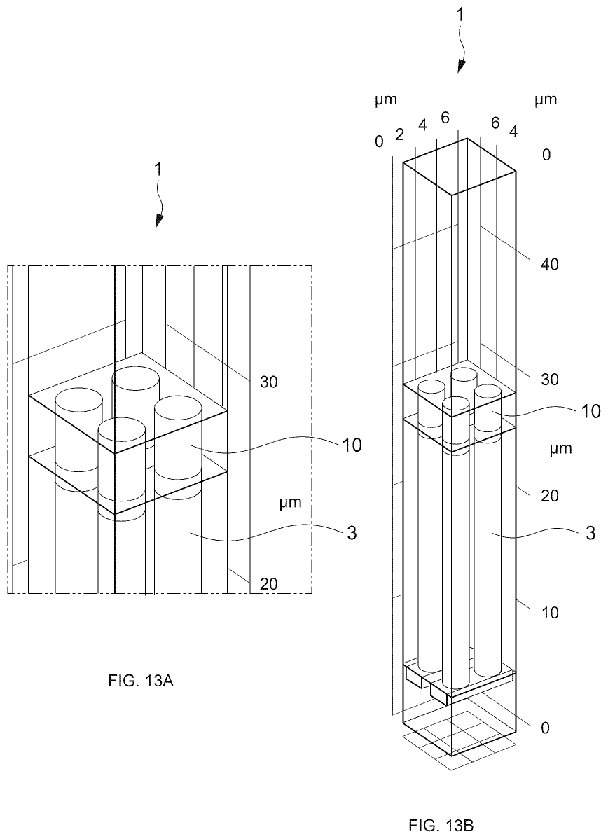

FIG. 13 is a schematic view showing the thermal detection element 1 according to the present technology.

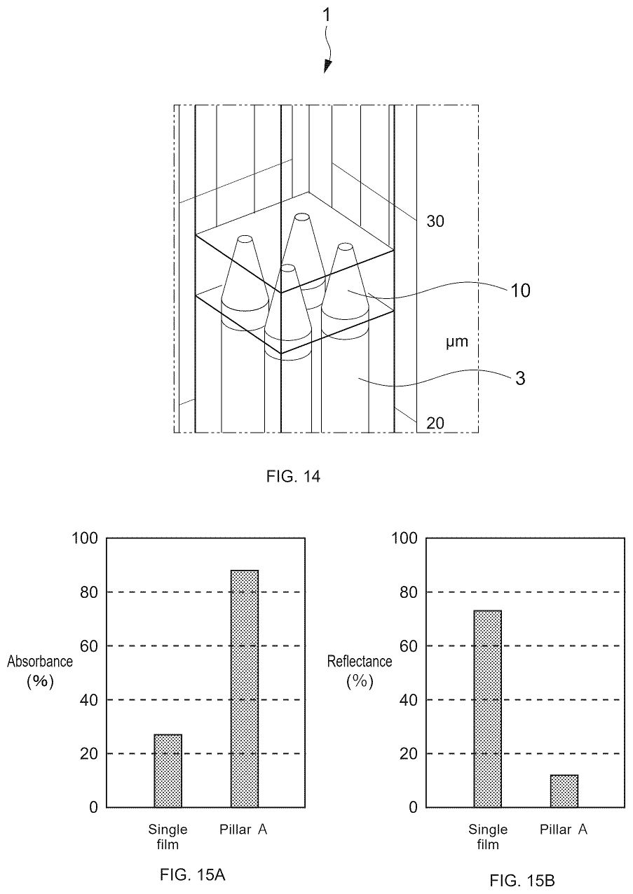

FIG. 14 is a schematic view showing the thermal detection element 1 according to the present technology.

FIG. 12 schematically shows the four thermal detectors 26 and the infrared absorbing film 33 that are included in the thermal detection element 24 in the comparative example. Hereinafter, the infrared absorbing film 33 in this example may be referred to as a single film.

A and B of FIG. 13 schematically show the four thermal detectors 3 and the four infrared absorbers 10 that are included in the thermal detection element 1 according to the present technology. Note that A of FIG. 13 is an enlarged view of the area around the infrared absorbers 10 in B of FIG. 13. The four infrared absorbers 10 each have a cylindrical, non-tapered shape. Hereinafter, the infrared absorber 10 with a cylindrical shape in this example may be referred to as a pillar A.

In the example shown in FIG. 14, the four infrared absorbers 10 included in the thermal detection element 1 according to the present technology each have a tapered, conical shape. Hereinafter, the infrared absorber 10 with a conical shape in this example may be referred to as a pillar B.

### Experiment 1

The inventors performed a simulation to compare the absorbance and the like in the single film and the pillar A. In this experiment, the following values are used as an electrical conductivity σ [S/m] and a relative permittivity εᵣ of each part.
Atmosphere: σ=0, εᵣ=1
Infrared absorber 10 (infrared absorbing film 33): σ=10⁵, εᵣ=10
Warm-point electrodes 9 and 31: σ=6×10⁷, εᵣ=10
Thermoelectric pillars: σ=10^{5, ε}ᵣ=10
Insulating filler materials 4 and 34: σ=0, εᵣ=2

Note that the thermoelectric pillars refer to the p-type thermoelectric conversion materials 6 and 28, the n-type thermoelectric conversion materials 8 and 30, and the like. Under those conditions, calculations were performed by varying the incident light in the range of a wavelength λ=8 to 14 [μm], an incidence angle perpendicular to the plane α=0 to 60 [deg], and an in-plane incidence angle β=0 to 45 [deg], and the average values of absorbance and reflectance of each material were calculated.

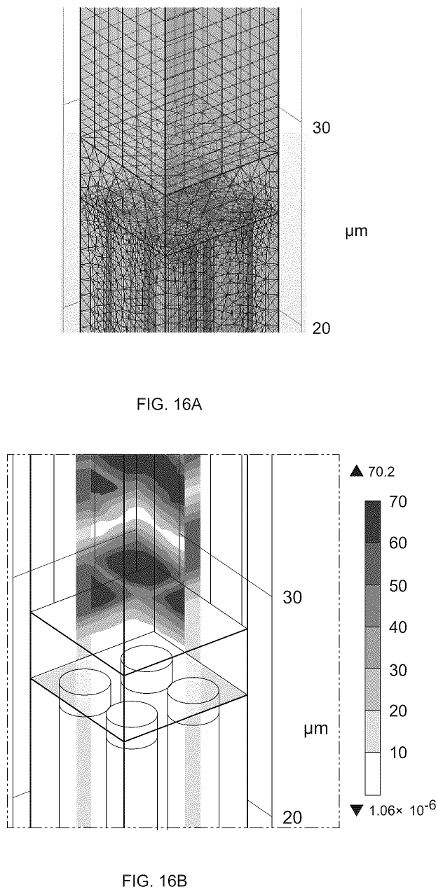

FIG. 15 shows graphs showing the absorbance and reflectance in the single film and the pillar A.

The average value of the absorbance in the single film is 27%. On the other hand, the average value of the absorbance in the pillar A is 888. Additionally, the average value of the reflectance in the single film is 738. On the other hand, the average value of the reflectance in the pillar A is 128. Thus, the results show that the pillar A has a higher absorbance and a lower absorptivity than the single film.

FIG. 16 is a schematic view showing the electric field distribution in the single film.

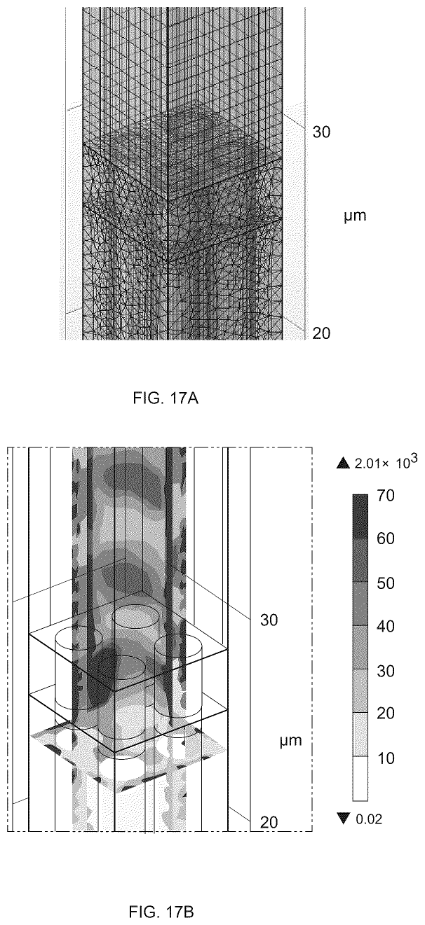

FIG. 17 is a schematic view showing the electric field distribution in the pillar A.

A of FIG. 16 and A of FIG. 17 show a mesh representation of the electric field distribution at a wavelength λ=10 [μm], an incidence angle perpendicular to the plane α=0 [deg], and an in-plane incidence angle β=0 [deg].

B of FIG. 16 and B of FIG. 17 each show an electric field distribution represented schematically by shades of gray. Each region has a stronger electric field as the color is closer to black. Additionally, the electric field becomes weaker as the color is closer to white. The inventors calculated the electric field distribution in this way and found that, in the single film, strong reflection to the upper side occurs due to diffraction, and the electric field incidence to the infrared absorbing film 33 is inhibited. In addition, the inventors also found that, in the pillar A, the reflection to the upper side is suppressed and more infrared light incidence into the element occurs, which can induce light absorption in the vicinity of the upper edge of the thermal detector 3.

Thus, in the pillar A, reflection is suppressed, which increases the amount of infrared light incident on the infrared absorber 10, resulting in efficient photothermal conversion in the vicinity of the upper edge of the thermal detector 3. As a result, the pillar A has a higher absorbance than the single film. In other words, the temperature difference generated inside the p-type thermoelectric conversion material 6 and the n-type thermoelectric conversion material 8 is larger, and the voltage generated by the thermoelectric effect is also larger. Therefore, infrared light is detected with high sensitivity.

The inventors performed the same simulation for the pillar B. When the electrical conductivity of the infrared absorber 10 is σ=10⁵ [S/m], the results show that the average value of the absorbance in the pillar B is 88%, and the average value of the reflectance in the pillar B is 12%.

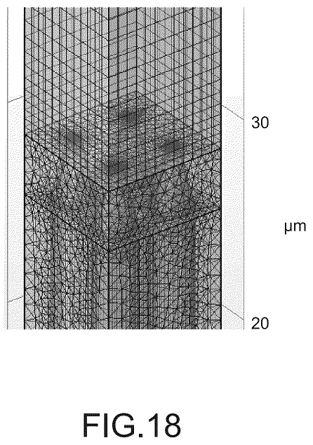

FIG. 18 is a schematic view showing the electric field distribution in the pillar B.

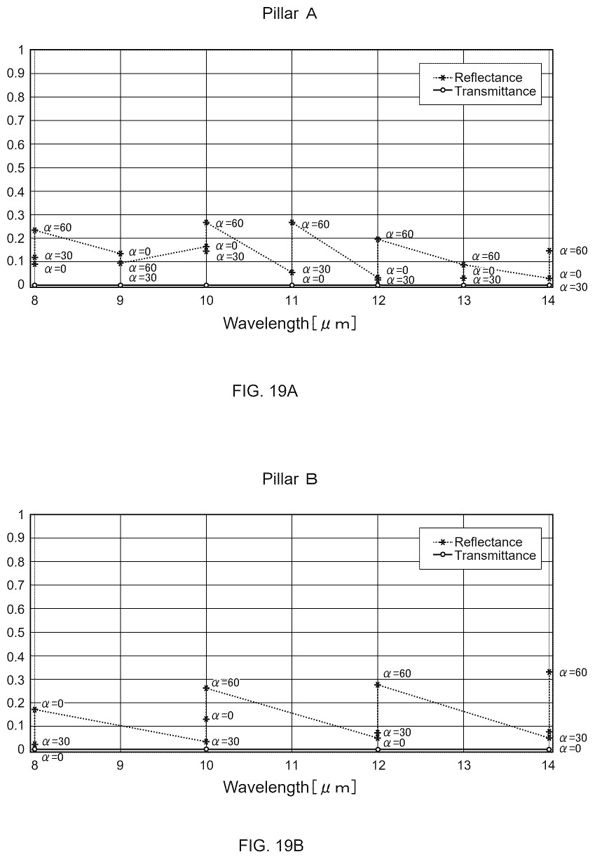

FIG. 19 shows graphs showing the relationship between a wavelength, an incidence angle perpendicular to the plane, a reflectance, and a transmittance in the pillar A and the pillar B.

A of FIG. 19 shows a graph showing the relationship between a wavelength, an incidence angle perpendicular to the plane, a reflectance, and a transmittance in the pillar A. The vertical axis of the graph represents a reflectance and a transmittance. The horizontal axis represents a wavelength [μm]. The reflectance is indicated by an asterisk (*) and a dashed line. Additionally, the transmittance is indicated by a circle and a solid line. Note that the in-plane incidence angle is β=0 [deg].

For example, at a wavelength λ=11 [μm], the values of the reflectance at the incidence angle perpendicular to the plane α=60 [deg] are generally under 30%. Looking at the entire graph, the values of the reflectance are all below 30%. In addition, the values of the transmittance are all approximately 0%. Therefore, in the pillar A, infrared light is absorbed in all wavelength ranges from λ=8 to 14 [μm] with an absorbance of 70% or more. Note that the absorbance can be calculated by subtracting the reflectance and the transmittance from 100%.

B of FIG. 19 shows a graph showing the relationship between a wavelength, an incidence angle perpendicular to the plane, a reflectance, and a transmittance in the pillar B. Looking at the entire graph, the values of the reflectance are all below 35%. In addition, the values of the transmittance are all approximately 0%. Therefore, in the pillar B, infrared light is absorbed in all wavelength ranges from λ=8 to 14 [μm] with an absorbance of 65% or more.

Thus, the pillar B has the same level of infrared absorption capability as the pillar A. Additionally, since the pillar B has a conical shape, its thermal capacity and thermal resistance are further reduced as compared to the pillar A. In addition, since the absorption of infrared light occurs in the location of the infrared absorber 10 that is closer to the warm-point electrode 9, it is possible to achieve an even faster response while maintaining high sensitivity.

### Experiment 2

The inventors performed a simulation to compare the absorbance and the like in the single film and the pillar A. In this experiment, the electrical conductivity of the infrared absorber 10 (infrared absorbing film 33) is set to σ=10⁶ [S/m]. Additionally, the range of the in-plane incidence angle is set to β=0 to 15 [deg]. Other conditions are the same as in Experiment 1.

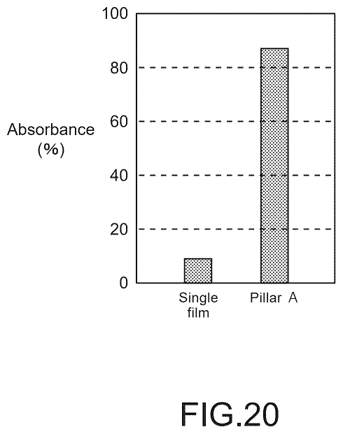

FIG. 20 is a graph showing the absorbance in the single film and the pillar A.

The absorbance of the single film is 98. On the other hand, the absorbance of the pillar A is 878. Thus, the results show that the pillar A has a higher absorbance than the single film.

Additionally, the reflectance of the single film was 91%. On the other hand, the reflectance of the pillar A was 13%. Thus, the results show that the pillar A has a lower reflectance than the single film.

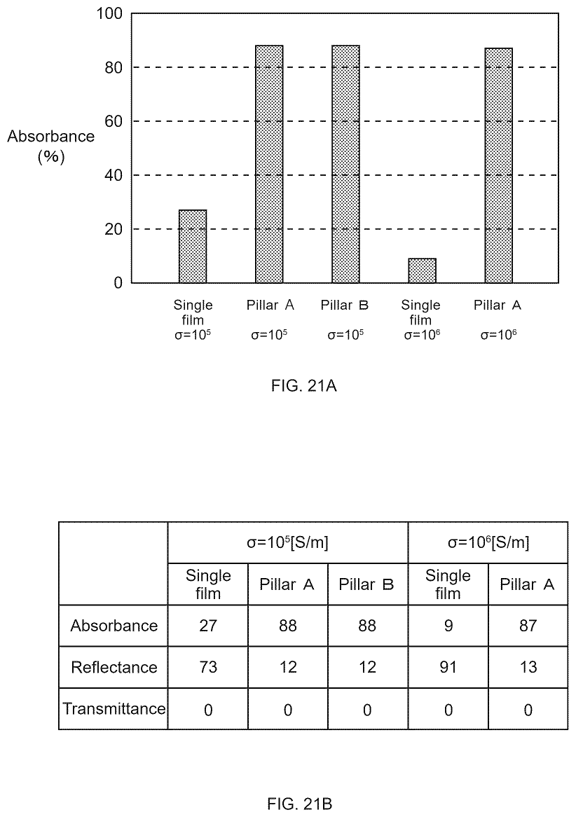

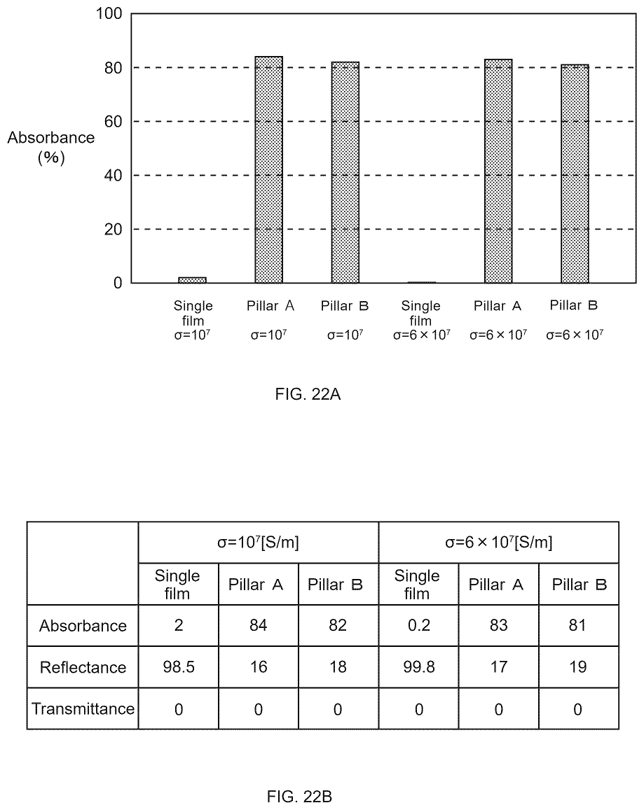

FIG. 21 shows a graph and a table showing the absorbance and the like in the single film, the pillar A, and the pillar B.

FIG. 21 shows the results of Experiments 1 and 2. It can be seen that the absorbance improves when the shape of the infrared absorber 10 is changed from the single film to the pillar A or the pillar B. It can also be seen that the absorbance is maintained when the electrical conductivity is increased from σ=10⁵ [S/m] to σ=10⁶ [S/m] in the pillar A.

### Experiment 3

The inventors performed a simulation to compare the absorbance and the like in the single film, the pillar A, and the pillar B. In this experiment, the electrical conductivity of the infrared absorber 10 (infrared absorbing film 33) is set to σ=10⁷ [S/m] and σ=6×10⁷ [S/m]. Note that σ=6×10⁷ [S/m] is the electrical conductivity of copper. Other conditions are the same as in Experiment 2.

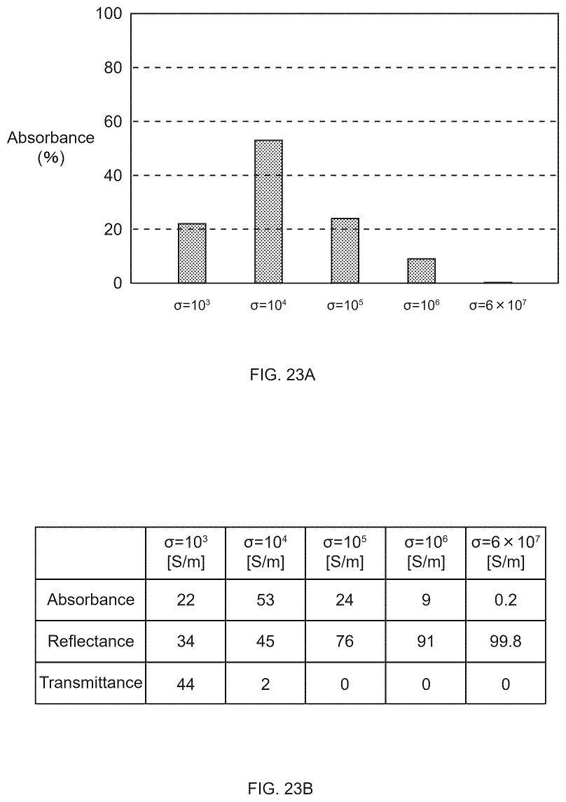

FIG. 22 shows a graph and a table showing the absorbance and the like in the single film, the pillar A, and the pillar B.

In this case as well, it can be seen that the absorbance improves when the shape of the infrared absorber 10 is changed from the single film to the pillar A or the pillar B. It can also be seen that a high absorbance is maintained in the pillar A and the pillar B at the electrical conductivity σ=10⁷ [S/m] and σ=6×10⁷ [S/m].

FIG. 23 shows a graph and a table showing the absorbance and the like in the single film.

In this example, the wavelength of incident light is λ=10 [μm], the incidence angle perpendicular to the plane is α=0 to 75 [deg], and the in-plane incidence angle is β=0 [deg]. In the case of the single film, a certain level of absorbance is shown at the electrical conductivity σ=10⁴ [S/m] and the like, but the absorbance becomes smaller as the electrical conductivity increases, and is almost zero at σ=6×10⁷ [S/m].

### Experiment 4

The inventors calculated a thermal time constant for the single film and the following pillars A′ and B′.
Pillar A′: obtained when the height of the pillar A is set to 1 [μm]
Pillar B′: obtained when the height of the pillar B is set to 1 [μm]

The density, specific heat, and thermal conductivity of the material property of each of the single film, the pillar A′, and the pillar B′ were assumed to be the same values. Additionally, an effective heat flow length L was assumed to be ½ [μm] for the pillar A′ and ¼ [μm] for the pillar B′. For simplicity, the average value of the top surface and the bottom surface was used in the calculation of the heat flow area for the pillar B′.

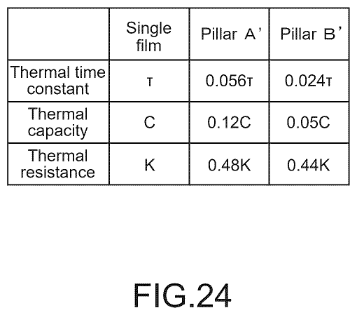

FIG. 24 is a table showing the thermal time constant and the like in the single film, the pillar A′, and the pillar B′.

The thermal time constant is calculated by the following equation.

$$τ = mc \times \frac{L}{κ A} \qquad [ Math . 1 ]$$

τ: thermal time constant
m: mass
c: specific heat
κ: thermal conductivity
L: heat flow length
A: heat flow area

Additionally, a thermal capacity is mc, and a thermal resistance is L/(κA).

It is possible to apply a material with high absorbance and high electrical conductivity to the pillar A′ and the pillar B′, which makes it possible to reduce the height and the mass m, as compared to the single film. In other words, the thermal capacity mc can be reduced as compared to the single film.

Additionally, a material with a high electrical conductivity is a material simultaneously having a high thermal conductivity κ. Further, in the pillar A′ and the pillar B′, photothermal conversion can be performed in the vicinity of the warm-point electrode 9, and the effective heat flow length L is shortened. Therefore, it is possible to reduce the thermal resistance L/(κA).

For the above reasons, the thermal time constants τ of the pillar A′ and the pillar B′ are smaller than that of the single film. Therefore, in the pillar A′ and the pillar B′, the heat of the received infrared light is quickly used for thermoelectric conversion, thus achieving a fast response.

As shown in the results of Experiments 1 to 4, the thermal detection element 1 (pillar A, pillar B, etc.) according to the present technology has a higher absorbance under various conditions than the thermal detection element 24 (single film) in the comparative example. This allows infrared light to be detected with high accuracy.

In the thermal detection element 1 according to the present technology, it is possible to use many types of materials for the material of the infrared absorber 10. For example, the electrical conductivity of copper is σ=6×10⁷ [S/m], and the single film has an absorbance close to zero at σ=6×10⁷ [S/m], so that copper cannot be used as a material for the infrared absorbing film 33. On the other hand, the pillar A and the pillar B have a high absorbance even at σ=6×10⁷ [S/m]. Therefore, it is possible to use copper as a material for the infrared absorber 10.

Further, in the thermal detection element 1 according to the present technology, it is possible to use not only copper but also various other materials with the electrical conductivity of approximately 10³ [S/m]<σ<10⁸ [S/m]. In other words, it is possible to use materials with high electrical conductivity, which cannot be introduced in the case of the single film.

Accordingly, this makes it possible to easily manufacture the infrared absorber 10. The method of manufacturing the infrared absorber 10 depends on the material, but since many types of materials can be used in the thermal detection element 1 according to the present technology, the degree of freedom in selecting the manufacture method is increased. Therefore, for example, it is possible to freely select a manufacture method with low formation cost or a manufacture method that requires less time for manufacture.

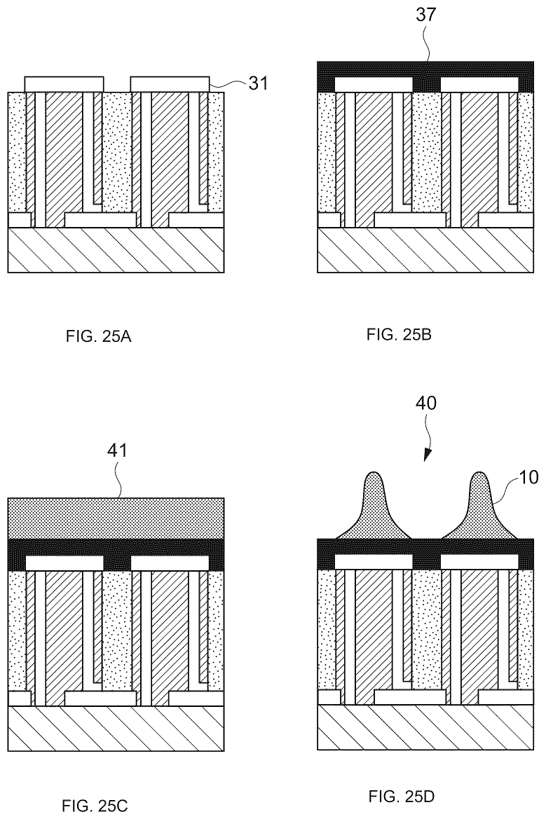

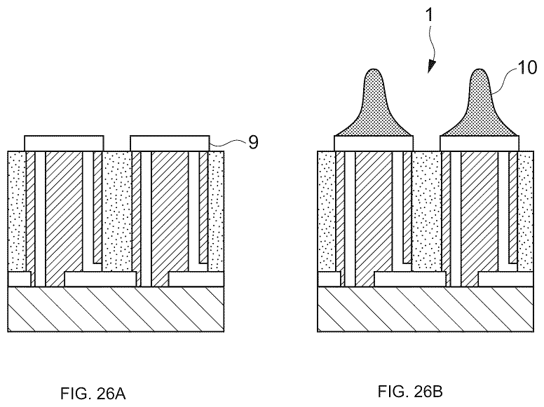

FIG. 25 is a cross-sectional view showing an example of the process of forming a thermal detection element 40 in a comparative example.

FIG. 26 is a cross-sectional view showing an example of the process of forming the thermal detection element 1 according to the present technology.

The thermal detection element 40 in the comparative example is a thermal detection element in which the infrared absorbing film 33 of the thermal detection element 24 in the comparative example shown in FIG. 11 is replaced with bell- shaped infrared absorbers 10. For the process of forming such a thermal detection element 40, for example, the process shown in FIG. 25 is conceivable.

First, an insulating layer 37 is formed on the top surface of each warm-point electrode 31 (B of FIG. 25). Further, an infrared light-absorbing layer 41 is formed on the top surface of the insulating layer 37 (C of FIG. 25). After that, an infrared absorber 10 is manufactured by etching the infrared light-absorbing layer 41 (D of FIG. 25).

In other words, in the thermal detection element 24 in the comparative example, if multiple independent infrared absorbers 10 are configured to achieve the effect of the present technology, after the stage in which the warm-point electrode 9 is manufactured (A of FIG. 25), multiple processes such as the formation of the insulating layer 37, the formation of the infrared light-absorbing layer 41, and etching are necessary.

Note that in the state where the insulating layer 37 is formed (B of FIG. 25), a method of forming the infrared absorber 10 directly without etching is also conceivable, but it is difficult to form the infrared absorber 10 directly because there is no electrode to serve as the base.

On the other hand, in the thermal detection element 1 according to the present technology, the thermal detection element 1 is formed in only one process in which the infrared absorber 10 is manufactured directly on the top of the warm- point electrode 9 (B of FIG. 26) after the stage in which the warm-point electrode 9 is manufactured (A of FIG. 26). In other words, as compared to the thermal detection element 40 in the comparative example, the thermal detection element 1 can be easily formed with fewer processes.

Additionally, if a catalyst is required for the manufacture of the infrared absorber 10, the catalyst is used as the material for the warm-point electrode 9, which enables the manufacture of the infrared absorber 10 without the preparation of a separate catalyst. This further facilitates the manufacture of the infrared absorber 10.

In addition, in the thermal detection element 1 according to the present technology, since each of the infrared absorbers 10 is disposed independently, the formation of the insulating layer 37 for insulating the warm-point electrodes 9 from each other is not necessary. Therefore, the time required to form the insulating layer 37 and the cost of forming the insulating layer 37 can be reduced.

Moreover, in the thermal detection element 1 according to the present technology, each of the thermal detectors 3 includes the p-type thermoelectric conversion material 6 and the n-type thermoelectric conversion material 8. This makes it possible to detect infrared light with high accuracy.

### Other Embodiments

The present technology is not limited to the embodiment described above, and various other embodiments can be implemented.

The thermal detection element 1 may be a thermoelectric conversion element that generates an electromotive force by the heat generated by the infrared absorber 10. For example, both ends of the cold-point electrode 5 shown in FIG. 1 are connected to various devices, and the devices are operated by the current flowing through them. Alternatively, both ends of the cold-point electrode 5 may be connected to a rechargeable battery or the like for charging.

This makes it possible to effectively use the energy generated by the absorption of infrared light.

An image sensor may be configured with a plurality of thermal detection elements 1. For example, a plurality of thermal detection elements 1 is disposed on the substrate 2. In other words, a plurality of blocks including a plurality of thermal detectors 3 is disposed. Each thermal detection element 1 functions as one pixel. Note that the substrate 2 may be a single substrate 2 or a plurality of substrates 2 coupled to each other.

Light emitted from an object is received by the thermal detection element 1 and converted into an electromotive force corresponding to the light. The electromotive force is then output as data for one pixel. Use of the configuration according to the present technology makes it possible to achieve an image sensor with even higher quality.

The thermal detection element, the method of manufacturing the thermal detection element, each processing flow, and the like described with reference to the drawings are merely embodiments and can be discretionally modified without departing from the gist of the present technology. In other words, any other configurations, algorithms, etc. for implementing the present technology can be adopted.

When the word “substantially” is used in the present disclosure, it is used only to facilitate understanding of the description, and there is no special meaning in the use/non-use of the word “substantially”. In other words, in the present disclosure, concepts defining shapes, sizes, positional relationships, states, and the like, such as “central”, “middle”, “uniform”, “equal”, “same”, “orthogonal”, “parallel”, “symmetric”, “extended”, “axial”, “columnar”, “cylindrical”, “ring-shaped”, “annular”, “conical”, “disc-shaped”, “square”, “circular”, “column-shaped”, “rotating body-shaped”, “tapered”, “non-tapered”, “pillar-shaped”, “bell-shaped”, “normal distribution-shaped”, “thread-shaped”, “needle-shaped”, “arborescens”, “nanowire-shaped”, “whisker-shaped”, “dendrite-shaped”, “uneven”, “membrane-shaped”, “zigzag”, “curved”, and “umbrella-shaped”, are concepts including “substantially central”, “substantially middle”, “substantially uniform”, “substantially equal”, “substantially the same”, “substantially orthogonal”, “substantially parallel”, “substantially symmetric”, “substantially extended”, “substantially axial”, “substantially columnar”, “substantially cylindrical”, “substantially ring-shaped”, “substantially annular”, “substantially conical”, “substantially disc-shaped”, “substantially square”, “substantially circular”, “substantially column-shaped”, “substantially rotating body-shaped”, “substantially tapered”, “substantially non-tapered”, “substantially pillar-shaped”, “substantially bell-shaped”, “substantially normal distribution-shaped”, “substantially thread-shaped”, “substantially needle-shaped”, “substantially arborescens”, “substantially nanowire-shaped”, “substantially whisker-shaped”, “substantially dendrite-shaped”, “substantially uneven”, “substantially membrane-shaped”, “substantially zigzag”, “substantially curved”, and “substantially umbrella-shaped”. For example, the states included in a predetermined range (e.g., range of ±10%) with reference to “completely central”, “completely middle”, “completely uniform”, “completely equal”, “completely the same”, “completely orthogonal”, “completely parallel”, “completely symmetric”, “completely extended”, “completely axial”, “completely columnar”, “completely cylindrical”, “completely ring-shaped”, “completely annular”, “completely conical”, “completely disc-shaped”, “completely square”, “completely circular”, “completely column-shaped”, “completely rotating body-shaped”, “completely tapered”, “completely non-tapered”, “completely pillar-shaped”, “completely bell-shaped”, “completely normal distribution-shaped”, “completely thread-shaped”, “completely needle-shaped”, “completely arborescens”, “completely nanowire-shaped”, “completely whisker-shaped”, “completely dendrite-shaped”, “completely uneven”, “completely membrane-shaped”, “completely zigzag”, “completely curved”, and “completely umbrella-shaped”, and the like are also included. Therefore, even if the word “substantially” is not added, the concept that is expressed by adding so-called “substantially” thereto can be included. To the contrary, the complete states are not necessarily excluded from the states expressed by adding the word “substantially”.

In the present disclosure, expressions using the term “than” such as “larger than A” and “smaller than A” are expressions that comprehensively include concepts that include the case of being equal to A and concepts that do not include the case of being equal to A. For example, “larger than A” is not limited to the case where it does not include “equal to A”; however, it also includes “equal to or larger than A”. Further, “smaller than A” is not limited to “less than A”; it also includes “equal to or smaller than A”. Upon implementation of the present technology, specific settings and other settings may be appropriately employed from the concepts that are included in “larger than A” and “smaller than A” to achieve the effects described above.

At least two of the features among the features described above according to the present technology can also be combined. In other words, various features described in the respective embodiments may be combined discretionarily regardless of the embodiments. Further, the various effects described above are merely illustrative and not restrictive, and other effects may be exerted.

Note that the present technology can also be configured as follows.

(1) A thermal detection element, including:
a substrate; and
a plurality of thermal detectors disposed on the substrate, in which
each of the plurality of thermal detectors includes
   a first electrode,
   a second electrode disposed on the substrate,
   a thermoelectric converter disposed between the first electrode and the second electrode, and
   an absorber that is disposed on the first electrode, and absorbs infrared rays and generates heat, and
the absorber included in each of the plurality of thermal detectors is configured to be separated from the absorber of another one of the thermal detectors.

(2) The thermal detection element according to (1), in which
the absorber has a shape of a rotating body, and has a bottom surface that is in contact with the first electrode, and a vertex located on the central axis of the rotating body.

(3) The thermal detection element according to (1) or (2), in which
the absorber has a shape of a column, and has a bottom surface that is in contact with the first electrode.

(4) The thermal detection element according to any one of (1) to (3), in which
the absorber includes a plurality of separate absorbers separated from each other.

(5) The thermal detection element according to (4), in which
each of the plurality of separate absorbers has a thread-like shape, a needle-like shape, or an arborescens shape.

(6) The thermal detection element according to any one of (1) to (5), in which
the absorber is formed of a material having an electrical conductivity of 10³ (S/m) or more and 10⁸ (S/m) or less.

(7) The thermal detection element according to (6), in which
the absorber is formed of at least one selected from the group of elements consisting of aluminum, titanium, vanadium, copper, zinc, silver, tungsten, gold, lithium, beryllium, sodium, magnesium, potassium, calcium, strontium, barium, chromium, manganese, iron, cobalt, gallium, rubidium, molybdenum, indium, tin, hafnium, tantalum, carbon, silicon, germanium, arsenic, selenium, antimony, tellurium, and bismuth.

(8) The thermal detection element according to (6) or (7), in which
the absorber is formed of at least one of graphene, carbon nanotube, black phosphorus, or a chalcogenide containing at least one selected from the group of elements.

(9) The thermal detection element according to any one of (6) to (8), in which
the absorber is formed of at least one of an oxide containing at least one selected from the group of elements, a nitride containing at least one selected from the group of elements, an oxynitride containing at least one selected from the group of elements, or a halide containing at least one selected from the group of elements.

(10) The thermal detection element according to any one of (6) to (9), in which
the absorber is formed of a conductive polymer.

(11) The thermal detection element according to (10), in which
the absorber is formed of polypyrrole.

(12) The thermal detection element according to any one of (1) to (11), in which
the absorber is formed with the first electrode as a catalyst.

(13) The thermal detection element according to any one of (1) to (12), in which
the thermoelectric converter includes a p-type thermoelectric conversion material and an n-type thermoelectric conversion material.

(14) The thermal detection element according to any one of (1) to (13), in which
the thermal detection element is a thermoelectric conversion element that generates an electromotive force by the heat generated by the absorber.

(15) A method of manufacturing a thermal detection element, including:
a thermal detection member forming process of forming a plurality of thermal detection members on a substrate, each of the plurality of thermal detection members including a first electrode, a second electrode disposed on the substrate, and a thermoelectric converter disposed between the first electrode and the second electrode; and
an absorber forming process of forming, on the first electrode included in each of the plurality of thermal detection members, an absorber that absorbs infrared rays and generates heat, in which
the absorber forming process includes forming the absorber such that the absorbers respectively formed for the plurality of thermal detection members are configured to be separated from each other.

(16) An image sensor, including:
a substrate; and
a plurality of thermal detection elements disposed on the substrate, in which
each of the plurality of thermal detection elements includes a plurality of thermal detectors disposed on the substrate,
each of the plurality of thermal detectors includes
   a first electrode,
   a second electrode disposed on the substrate,
   a thermoelectric converter disposed between the first electrode and the second electrode, and
   an absorber that is disposed on the first electrode, and absorbs infrared rays and generates heat, and
the absorber included in each of the plurality of thermal detectors is configured to be separated from the absorber of another one of the thermal detectors.

### Reference Signs List

1 thermal detection element
2 substrate
3 thermal detector
5 cold-point electrode
6 p-type thermoelectric conversion material
8 n-type thermoelectric conversion material
9 warm-point electrode
10 infrared absorber
11 central axis
12 infrared light
16 separate infrared absorber

1. A thermal detection element, comprising:
a substrate; and
a plurality of thermal detectors disposed on the substrate, wherein
each of the plurality of thermal detectors includes
a first electrode,
a second electrode disposed on the substrate,
a thermoelectric converter disposed between the first electrode and the second electrode, and
an absorber that is disposed on the first electrode, and absorbs infrared rays and generates heat, and
the absorber included in each of the plurality of thermal detectors is configured to be separated from the absorber of another one of the thermal detectors.

2. The thermal detection element according to claim 1, wherein
the absorber has a shape of a rotating body, and has a bottom surface that is in contact with the first electrode, and a vertex located on the central axis of the rotating body.

3. The thermal detection element according to claim 1, wherein
the absorber has a shape of a column, and has a bottom surface that is in contact with the first electrode.

4. The thermal detection element according to claim 1,
the absorber includes a plurality of separate absorbers separated from each other.

5. The thermal detection element according to claim 4, wherein
each of the plurality of separate absorbers has a thread-like shape, a needle-like shape, or an arborescens shape.

6. The thermal detection element according to claim 1, wherein
the absorber is formed of a material having an electrical conductivity of 10³ (S/m) or more and 10⁸ (S/m) or less.

7. The thermal detection element according to claim 6, wherein
the absorber is formed of at least one selected from the group of elements consisting of aluminum, titanium, vanadium, copper, zinc, silver, tungsten, gold, lithium, beryllium, sodium, magnesium, potassium, calcium, strontium, barium, chromium, manganese, iron, cobalt, gallium, rubidium, molybdenum, indium, tin, hafnium, tantalum, carbon, silicon, germanium, arsenic, selenium, antimony, tellurium, and bismuth.

8. The thermal detection element according to claim 6, wherein
the absorber is formed of at least one of graphene, carbon nanotube, black phosphorus, or a chalcogenide containing at least one selected from the group of elements.

9. The thermal detection element according to claim 6,
the absorber is formed of at least one of an oxide containing at least one selected from the group of elements, a nitride containing at least one selected from the group of elements, an oxynitride containing at least one selected from the group of elements, or a halide containing at least one selected from the group of elements.

10. The thermal detection element according to claim 6, wherein
the absorber is formed of a conductive polymer.

11. The thermal detection element according to claim 10, wherein
the absorber is formed of polypyrrole.

12. The thermal detection element according to claim 1, wherein
the absorber is formed with the first electrode as a catalyst.

13. The thermal detection element according to claim 1, wherein
the thermoelectric converter includes a p-type thermoelectric conversion material and an n-type thermoelectric conversion material.

14. The thermal detection element according to claim 1, wherein
the thermal detection element is a thermoelectric conversion element that generates an electromotive force by the heat generated by the absorber.

15. A method of manufacturing a thermal detection element, comprising:
a thermal detection member forming process of forming a plurality of thermal detection members on a substrate, each of the plurality of thermal detection members including a first electrode, a second electrode disposed on the substrate, and a thermoelectric converter disposed between the first electrode and the second electrode; and
an absorber forming process of forming, on the first electrode included in each of the plurality of thermal detection members, an absorber that absorbs infrared rays and generates heat, wherein
the absorber forming process includes forming the absorber such that the absorbers respectively formed for the plurality of thermal detection members are configured to be separated from each other.

16. An image sensor, comprising:
a substrate; and
a plurality of thermal detection elements disposed on the substrate, wherein
each of the plurality of thermal detection elements includes a plurality of thermal detectors disposed on the substrate,
each of the plurality of thermal detectors includes
a first electrode,
a second electrode disposed on the substrate,
a thermoelectric converter disposed between the first electrode and the second electrode, and
an absorber that is disposed on the first electrode, and absorbs infrared rays and generates heat, and
the absorber included in each of the plurality of thermal detectors is configured to be separated from the absorber of another one of the thermal detectors.
